(19) United States
(12) Patent Application Publication
(10) Pub. No.: US 2009/0056993 A1
(43) Pub. Date: Mar. 5, 2009

(54) METHOD FOR FORMING CURED FILM

(75) Inventors: Hiroyuki Satou, Ichihara-shi (JP); Setsuo Itami, Ichihara-shi (JP)

Correspondence Address: HOGAN & HARTSON LLP;IP GROUP, COLUMBIA SQUARE, 555 THIRTEENTH STREET, N.W., WASHINGTON, DC, 20004, US

(73) Assignee: CHISSO CORPORATION, Osaka (JP)

(21) Appl. No.: 12/199,681

(22) Filed: Aug. 27, 2008

(30) Foreign Application Priority Data
Aug. 27, 2007 (JP) 2007-219591

(51) Int. Cl. H05K 1/00; B05D 5/00; B32B 3/10

(52) U.S. Cl. 174/258; 427/256; 428/195.1

(57) ABSTRACT

The invention provides a method for forming a cured film, comprising discharging an ink-jet ink, which comprises predetermined compounds, whose viscosity at 25° C. is approximately 150 to approximately 3,000 mPa·s, from an ink-jet head at a discharging temperature of approximately 80 to approximately 150° C., which has a low degree of spread of an ink-jet ink after landing, and which is able to form a highly-fine pattern.

### CROSS REFERENCE TO RELATED APPLICATIONS

This application claims priority under 35 U.S.C. §119 to Japanese Patent Application No. JP 2007-219591, filed Aug. 27, 2007, which application is expressly incorporated herein by reference in its entirety.

1. Field of the Invention

The invention relates to a method for forming a cured film using an ink-jet ink. Specifically, the invention relates to a method for forming a cured film using an ink-jet ink used to produce a printed-wiring assembly and the like. Moreover, the invention relates to an electronic circuit substrate on which a cured film is formed according to the above-described method and an electronic component having the electronic circuit substrate.

2. Background of the Invention

Patterned cured films are used on many portions, such as coverlays and etching resists, of electronic circuit substrates. Many types of curable compositions have been suggested to be used for this application. One typical method for forming a patterned cured film using a photosetting composition is a photolithographic method in which ultraviolet is irradiated via a mask having a desired pattern and portions which do not receive ultraviolet irradiation are removed by means of image development.

However, in this method, a dedicated line equipped with an exposure device, a developing machine and the like is required, and large equipment investments are required.

Under the above-described circumstances, recently, ink-jet methods having advantages such as small equipment investments, no use of developing solution, high efficiency in the use of materials and the like have been suggested, and compositions to be used in the methods (ink-jet inks) have also been suggested (see, e.g., Japanese Laid-Open Patent Publication No. 2003-302642). Moreover, photosetting ink-jet inks for use in the ink-jet methods have also been suggested (see, e.g., International Publication WO 2004/099272 pamphlet). Furthermore, viscosities and jetting temperatures which are suitable for the ink-jet methods have also been suggested (see, e.g., Japanese Laid-Open Patent Publication No. 2004-188857).

However, when patterning (printing) is performed using the ink-jet inks and the ink-jet methods described in the above-described documents, droplets discharged from an ink-jet head are spread over a substrate after landed thereon. Therefore, due to the decrease in resolution, it is difficult to form a highly-fine pattern.

Under the above-described circumstances, for example, a method for forming a cured film, in which the degree of spread of droplets discharged from an ink-jet head after landing is low and a highly-fine pattern can be formed, is desired.

### SUMMARY OF THE INVENTION

The inventors found that a highly-fine pattern can be formed by employing a method for forming a cured film comprising discharging an ink-jet ink, which comprises a compound having a specific structure and has a predetermined viscosity, from an ink-jet head at a predetermined discharging temperature, and completed the invention.

The invention provides a method for forming a cured film as described below. Note that the expression “(meth)acrylate” is sometimes used herein in order to indicate both “acrylate” and “methacrylate”.

[1] A method for forming a cured film including discharging an ink-jet ink, which includes at least one compound selected from the group consisting of compounds represented by general formula (1) below and compounds represented by general formula (2) below, and whose viscosity at 25° C. is approximately 150 to approximately 3,000 mPa·s, from an ink-jet head at a discharging temperature of approximately 80 to approximately 150° C.,

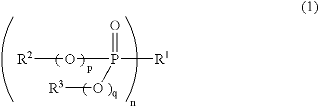

wherein in the formula (1), R¹ is an organic group having 1 to 100 carbon atoms; R² and R³ are each independently alkyl having 1 to 20 carbon atoms, phenyl, phenyl in which any hydrogen is replaced by alkyl having 1 to 5 carbon atoms, or phenyl in which any hydrogen is replaced by phenyl, wherein R² and R³ may bind to each other to form a cyclic group(s); n is an integer from 1 to 10; and p and q are each independently 0 or 1, and

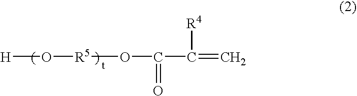

wherein in the formula (2), R⁴ is hydrogen or methyl; R⁵ is alkylene having 2 to 20 carbon atoms which may have a cyclic structure(s); and t is an integer from 1 to 30.

[2] The method for forming a cured film according to Item [1], including discharging an ink-jet ink, which comprises at least one compound selected from compounds represented by the general formula (1) and at least one compound selected from compounds represented by the general formula (2), and whose viscosity at 25° C. is approximately 150 to approximately 3,000 mPa·s, from the ink-jet head at a discharging temperature of approximately 80 to approximately 150° C.

[3] A method for forming a cured film including discharging an ink-jet ink, which includes at least one compound selected from the group consisting of compounds represented by general formula (3) below and compounds represented by general formula (4) below, and whose viscosity at 25° C. is approximately 150 to approximately 3,000 mPa·s, from an ink-jet head at a discharging temperature of approximately 80 to approximately 150° C.,

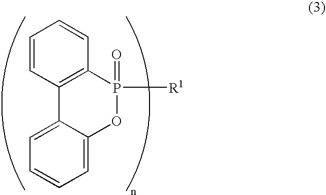

wherein in the formula (3), R¹ is an organic group having 1 to 100 carbon atoms; and n is an integer from 1 to 10, and

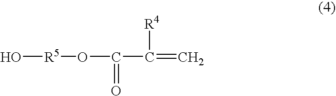

wherein in the formula (4), R⁴ is hydrogen or methyl; and R⁵ is alkylene having 2 to 8 carbon atoms which may have a cyclic structure(s).

[4] The method for forming a cured film according to Item [3], including discharging an ink-jet ink, which includes at least one compound selected from compounds represented by the general formula (3) and at least one compound selected from compounds represented by the general formula (4), and whose viscosity at 25° C. is approximately 150 to approximately 3,000 mPa·s, from the ink-jet head at a discharging temperature of approximately 80 to approximately 150° C.

[5] The method for forming a cured film according to any one of Items [1] to [4], wherein the ink-jet ink further comprises a photopolymerization initiator.

[6] The method for forming a cured film according to any one of Items [1] to [5], wherein the ink-jet ink includes a solvent, whose boiling point under ordinary pressure is approximately 300° C. or lower, in an amount of approximately 0 to approximately 10 wt % based on the total amount of the ink-jet ink.

[7] The method for forming a cured film according to Item [5] or [6], wherein the photopolymerization initiator is bis(2,4,6-trimethylbenzoyl)phenylphosphineoxide or 2,4,6-trimethylbenzoyldiphenylphosphineoxide.

[8] The method for forming a cured film according to any one of Items [5] to [7], wherein in the ink-jet ink, the total weight of the compounds represented by the general formula (1) and the compounds represented by general the formula (2) or the total weight of the compounds represented by the general formula (3) and the compounds represented by the general formula (4) is approximately 50 to approximately 100 wt %; the weight of the solvent is approximately 0 to approximately 10 wt %; the weight of the photopolymerization initiator is approximately 0 to approximately 20 wt %; and the total weight of “a different radical polymerizable monomer(s)” and “a compound(s) selected from the group consisting of compounds having two or more oxiranes or oxetanes” is approximately 0 to approximately 50 wt %, based on the whole weight of the ink-jet ink.

[9] The method for forming a cured film according to any one of Items [1] to [8], wherein R¹ is an organic group having 1 to 100 carbon atoms which has a radical polymerizable double bond.

[10] The method for forming a cured film according to any one of Items [1] to [9], wherein R⁵ is ethylene, propylene or butylene.

[11] The method for forming a cured film according to Item [3] or [4], wherein the compounds represented by the general formula (3) are compounds represented by general formula (5), (6), (7) or (8) below,

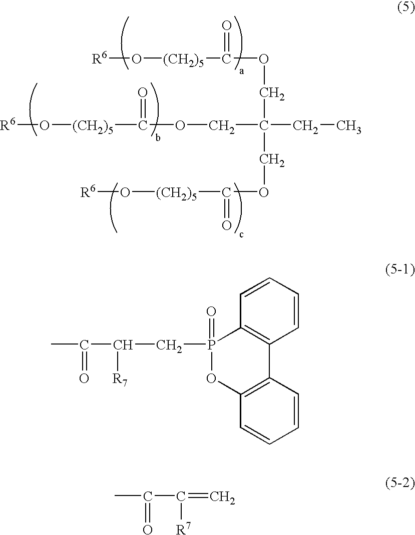

wherein in the formula (5), a, b and c are each independently an integer from 0 to 10; 1 or 2 of three R⁶s are a group represented by the formula (5-1), and the remaining R⁶(s) is a group represented by the formula (5-2); and R⁷ is hydrogen or methyl,

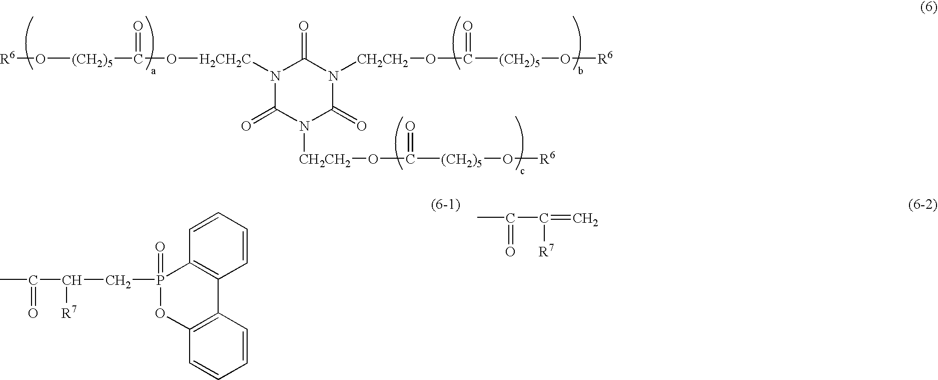

wherein in the formula (6), a, b and c are each independently an integer from 0 to 10; 1 or 2 of three R⁶s are a group represented by the formula (6-1), and the remaining R⁶(s) is a group represented by the formula (6-2); and R⁷ is hydrogen or methyl,

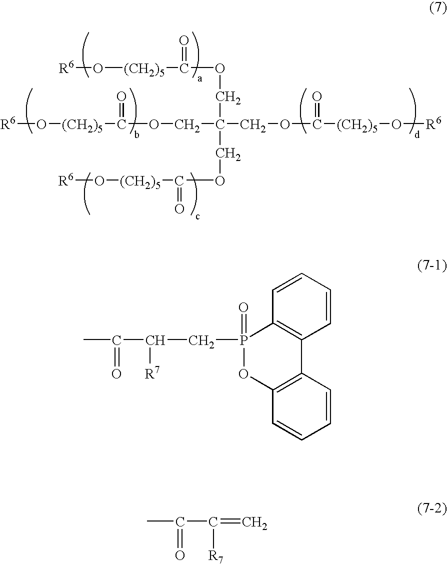

wherein in the formula (7), a, b, c and d are each independently an integer from 0 to 10; 1 to 3 of four R⁶s are a group represented by the formula (7-1), and the remaining R⁶(s) is a group represented by the formula (7-2); and R⁷ is hydrogen or methyl, and

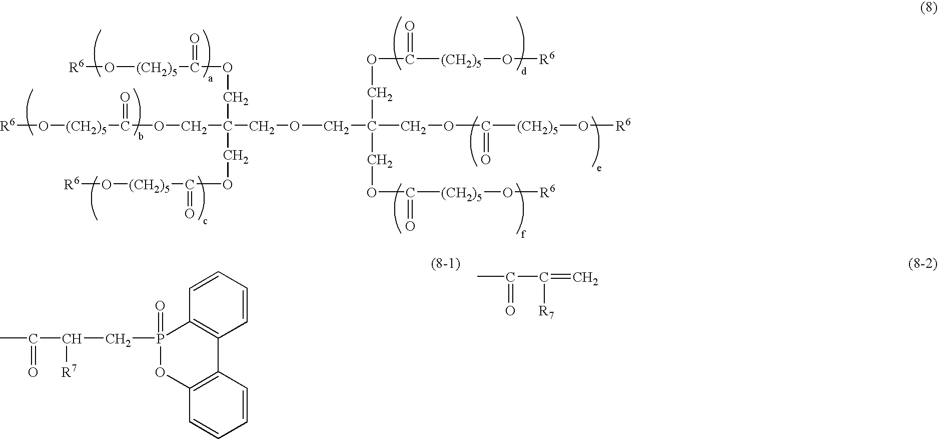

wherein in the formula (8), a, b, c, d, e and f are each independently an integer from 0 to 10; 1 to 5 of six R⁶s are a group represented by the formula (8-1), and the remaining R⁶(s) is a group represented by the formula (8-2); and R⁷ is hydrogen or methyl.

[12] The method for forming a cured film according to any one of Items [1] to [11], wherein the viscosity of the ink-jet ink at 25° C. is approximately 150 to approximately 300 mPa·s.

[13] The method for forming a cured film according to any one of Items [1] to [12], wherein the discharging temperature is approximately 90 to approximately 140° C.

[14] The method for forming a cured film according to any one of Items [1] to [12], wherein the discharging temperature is approximately 100 to approximately 130° C.

[15] A cured film formed using the method for forming a cured film according to any one of Items [1] to [14].

[16] A patterned cured film formed using the method for forming a cured film according to any one of Items [1] to [14].

[17] An electronic circuit substrate in which the cured film according to Item [15] or [16] is formed on a substrate.

[18] An electronic component having the electronic circuit substrate according to Item [17].

When employing the method for forming a cured film according to the preferred embodiment of the invention, a highly-fine pattern can be formed, and the method is useful, for example, as a method for forming a cured film for an electronic circuit substrate.

### DETAILED DESCRIPTION OF THE INVENTION

1. Ink-Jet Ink Used for Forming a Cured Film

An ink-jet ink to be used in the method for forming a cured film is an ink, which comprises at least one compound selected from the group consisting of compounds represented by the above-described general formulae (1) and (2), and whose viscosity at 25° C. is approximately 150 to approximately 3,000 mPa·s. The viscosity of the ink at 25° C. is preferably approximately 150 to approximately 1,000 mPa·s, more preferably approximately 150 to approximately 500 mPa·s, and even more preferably approximately 150 to approximately 300 mPa·s.

The above-described ink-jet ink can be obtained by mixing and stirring the components described in detail below in suitable amounts and by filtering the obtained mixture using a membrane filter having the pore diameter of approximately 1 μm or the like. The smaller the pore diameter of the membrane filter, the smaller the amount of contamination. The pore diameter can be selected depending on specifications desired for ink (e.g., preventability of clogging of an ink-jet nozzle and the like), but the pore diameter is preferably approximately 0.2 to approximately 10 μm, more preferably approximately 0.2 to approximately 5 μm, and even more preferably approximately 0.5 to approximately 3 μm.

The ink-jet ink may be colorless or colored. The term “ink” generally means a colored liquid which is used for writing, printing and the like. The term “ink-jet ink” of the invention can also be used to indicate this meaning. However, for example, when using the ink-jet ink for forming a cured film for an electronic circuit substrate, the ink-jet ink is not required to be colored and may be colorless.

1.1. Compounds Represented by General Formula (1)

The above-described ink-jet ink preferably comprises a compound represented by the above-described general formula (1).

Regarding the “organic group having 1 to 100 carbon atoms” in R¹, it is preferably an organic group having 4 to 90 carbon atoms, more preferably an organic group having 10 to 80 carbon atoms, and even more preferably an organic group having 15 to 70 carbon atoms. Moreover, it is preferably an organic group having a radical polymerizable double bond. A radical polymerizable double bond is a carbon-carbon double bond. Specific examples of the double bonds include acryloyl, methacryloyl, styryl, maleimide, vinyl and allyl. Acryloyl is particularly preferable.

Regarding the “alkyl having 1 to 20 carbon atoms” in R² and R³, it is preferably an alkyl having 2 to 12 carbon atoms, more preferably an alkyl having 3 to 8 carbon atoms, and even more preferably an alkyl having 4 to 6 carbon atoms. Specific examples thereof include ethyl, propyl, butyl, heptyl, hexyl and octyl.

Regarding the “phenyl in which any hydrogen is replaced by alkyl having 1 to 5 carbon atoms” in R² and R³, the number of alkyls for replacement is preferably 1 to 3, more preferably 1 to 2, and even more preferably 1. The replacement position may be any of the ortho position, the meta position and the para position. It is preferably the meta position or the para position, and more preferably the meta position. Specific examples of the “alkyl having 1 to 5 carbon atoms” include methyl, ethyl, propyl, butyl and heptyl. Specific examples of the “phenyl in which any hydrogen is replaced by alkyl having 1 to 5 carbon atoms” include 3-methylphenyl, 3,4-dimethylphenyl and 3-propylphenyl.

Regarding the “phenyl in which any hydrogen is replaced by phenyl” in R² and R³, the number of phenyls for replacement is preferably 1 to 3, more preferably 1 to 2, and even more preferably 1. The replacement position may be any of the ortho position, the meta position and the para position. It is preferably the meta position or the para position, and more preferably the meta position. Specific examples of the “phenyl in which any hydrogen is replaced by phenyl” include 3-phenylphenyl and 3,4-diphenylphenyl.

Further, R² and R³ may bind to each other to form a cyclic group. One specific example thereof has a structure represented by the following formula.

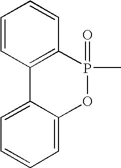

n is an integer from 1 to 10, preferably an integer from 1 to 8, even more preferably an integer from 1 to 7, and still more preferably an integer from 1 to 6.

p and q are each independently 0 or 1. Preferably, p is 0 and q is 1.

The compound represented by the general formula (1) is preferably a compound represented by the above-described general formula (3), and more preferably a compound represented by the above-described general formula (5), (6), (7) or (8).

Examples of R¹ and n in the formula (3) include the same things as those in the above-described formula (1), and the same things are preferable.

a, b and c in the formula (5) are each independently preferably an integer from 0 to 10, more preferably an integer from 0 to 3, and even more preferably an integer from 0 to 1.

Three R⁶s in the formula (5) are constituted by 1 or 2 group(s) represented by the formula (5-1) and 2 or 1 group(s) represented by the formula (5-2), and preferably constituted by 1 group represented by the formula (5-1) and 2 groups represented by the formula (5-2).

R⁷ in the formula (5-1) and the formula (5-2) may be hydrogen or methyl, and preferably hydrogen.

Regarding a, b and c in the formula (6); the ratio between group(s) represented by the formula (6-1) and group(s) represented by the formula (6-2) constituting R⁶; and R⁷, examples thereof include the same things as those in the above-described formula (5), and the same things are preferable.

a, b, c and d in the formula (7) are each independently preferably an integer from 0 to 10, more preferably an integer from 0 to 3, and even more preferably an integer from 0 to 1.

Four R⁶s in the formula (7) are constituted by 1 to 3 group(s) represented by the formula (7-1) and 3 to 1 group(s) represented by the formula (7-2), preferably constituted by 1 to 2 group(s) represented by the formula (7-1) and 3 to 2 groups represented by the formula (7-2), and more preferably constituted by 1 group represented by the formula (7-1) and 3 groups represented by the formula (7-2).

R⁷ in the formula (7-1) and the formula (7-2) may be hydrogen or methyl, and preferably hydrogen.

a, b, c, d, e and f in the formula (8) are each independently preferably an integer from 0 to 10, more preferably an integer from 0 to 3, and even more preferably an integer from 0 to 1.

Six R⁶s in the formula (8) are constituted by 1 to 5 group(s) represented by the formula (8-1) and 5 to 1 group(s) represented by the formula (8-2), preferably constituted by 1 to 4 group(s) represented by the formula (8-1) and 5 to 2 groups represented by the formula (8-2), more preferably constituted by 2 to 4 groups represented by the formula (8-1) and 4 to 2 groups represented by the formula (8-2), and even more preferably constituted by 4 groups represented by the formula (8-1) and 2 groups represented by the formula (8-2).

R⁷ in the formula (8-1) and the formula (8-2) may be hydrogen or methyl, and preferably hydrogen.

One example of the compound represented by the formula (5) is HFA-3003 (a compound represented by the formula (5), in which a=0, b=0, and c=0, and which has 1 group represented by the formula (5-1) and 2 groups represented by the formula (5-2)) manufactured by Showa Highpolymer Co., Ltd. (commercially available).

Further, one example of the compound represented by the formula (8) is HFA-6127 (a compound represented by the formula (8), in which a=1, b=1, c=1, d=1, e=1 and f=1, and which has 4 groups represented by the formula (8-1) and 2 groups represented by the formula (8-2)) manufactured by Showa Highpolymer Co., Ltd. (commercially available).

An ink-jet ink comprising these compounds is advantageous for forming a highly-fine pattern since the contact angle on a substrate made of polyimide, copper foil or the like is high and therefore droplets discharged from an ink-jet head are not spread over the substrate after landed thereon. In particular, when the ink has acryloyl in its molecule, no bleed out occurs even if a cured film is heated at a high temperature, and the ink has good adhesiveness to the substrate and chemical resistance.

1.2. Compounds Represented by General Formula (2)

The above-described ink-jet ink preferably comprises a compound represented by the above-described general formula (2).

R⁴ may be hydrogen or methyl, and preferably hydrogen. Regarding the “alkylene having 2 to 20 carbon atoms which may have a cyclic structure” in R it is preferably alkylene having 2 to 17 carbon atoms, more preferably alkylene having 2 to 12 carbon atoms, and even more preferably alkylene having 2 to 8 carbon atoms. Specific examples of the “cyclic structure” include a cyclohexane ring, a benzene ring and a bicyclo ring. Specific examples of the “alkylene having 2 to 20 carbon atoms which may have a cyclic structure” include ethylene, propylene, butylene and the structure represented by the following formula,

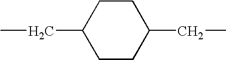

wherein t is an integer from 1 to 30, preferably an integer from 1 to 10, more preferably an integer from 1 to 4, and even more preferably 1.

The compound represented by the general formula (2) is preferably a compound represented by the above-described general formula (4), and more preferably 2-hydroxyethyl(meth)acrylate, 2-hydroxypropyl(meth)acrylate or 4-hydroxybutyl(meth)acrylate.

Examples of R⁴ and R⁵ in the formula (4) include the same things as those in the above-described formula (2), and the same things are preferable.

An ink-jet ink comprising these compounds is advantageous for forming a highly-fine pattern since the contact angle on a substrate made of polyimide, copper foil or the like is high and therefore droplets discharged from an ink-jet head are not spread over the substrate after landed thereon. Further, since the ink has hydroxy in its molecule, a cured film obtained has high adhesiveness to the above-described substrate.

1.3. Photopolymerization Initiator

The above-described ink-jet ink may comprise a photopolymerization initiator. By irradiating the ink-jet ink comprising the photopolymerization initiator with light, droplets discharged from an ink-jet head can be solidified before they are spread on a substrate after landed thereon. Therefore, it is advantageous for forming a highly fine pattern.

Specific examples of photopolymerization initiators include benzophenone, Michler's ketone, 4,4′-bis(diethylamino)benzophenone, xanthone, thioxanthone, isopropylxanthone, 2,4-diethylthioxanthone, 2-ethylanthraquinone, acetophenone, 2-hydroxy-2-methylpropiophenone, 2-hydroxy-2-methyl-4′-isopropylpropiophenone, 1-hydroxycyclohexylphenylketone, isopropylbenzoinether, isobutylbenzoinether, 2,2-diethoxyacetophenone, 2,2-dimethoxy-2-phenylacetophenone, camphorquinone, benzanthrone, 2-methyl-1-[4-(methylthio)phenyl]-2-morpholinopropane-1-one, 2-benzyl-2-dimethylamino-1-(4-morpholinophenyl)-butanone-1, ethyl 4-dimethylaminobenzoate, isoamyl 4-dimethylaminobenzoate, 4,4′-di(t-butylperoxycarbonyl)benzophenone, 3,4,4′-tri(t-butylperoxycarbonyl)benzophenone, 3,3′,4,4′-tetra(t-butylperoxycarbonyl)benzophenone, 3,3′,4,4′-tetra(t-hexylperoxycarbonyl)benzophenone, 3,3′-di(methoxycarbonyl)-4,4′-di(t-butylperoxycarbonyl)benzophenone, 3,4′-di(methoxycarbonyl)-4,3′-di(t-butylperoxycarbonyl)benzophenone, 4,4′-di(methoxycarbonyl)-3,3′-di(t-butylperoxycarbonyl)benzophenone, 1,2-octanedione, 1-[4-(phenylthio)phenyl]-,2-(o-benzoyloxime), 2-(4′-methoxystyryl)-4,6-bis(trichloromethyl)-s-triazine, 2-(3′,4′-dimethoxystyryl)-4,6-bis(trichloromethyl)-s-triazine, 2-(2′,4′-dimethoxystyryl)-4,6-bis(trichloromethyl)-s-triazine, 2-(2′-methoxystyryl)-4,6-bis(trichloromethyl)-s-triazine, 2-(4′-pentyloxystyryl)-4,6-bis(trichloromethyl)-s-triazine, 4-[p-N,N-di(ethoxycarbonylmethyl)]-2,6-di(trichloromethyl)-s-triazine, 1,3-bis(trichloromethyl)-5-(2′-chlorophenyl)-s-triazine, 1,3-bis(trichloromethyl)-5-(4′-methoxyphenyl)-s-triazine, 2-(p-dimethylaminostyryl)benzoxazol, 2-(p-dimethylaminostyryl)benzthiazole, 2-mercaptobenzothiazole, 3,3′-carbonylbis(7-diethylaminocoumarin), 2-(o-chlorophenyl)-4,4′,5,5′-tetraphenyl-1,2′-biimidazole, 2,2′-bis(2-chlorophenyl)-4,4′,5,5′-tetrakis(4-ethoxycarbonylphenyl)-1,2′-biimidazole, 2,2′-bis(2,4-dichlorophenyl)-4,4′,5,5′-tetraphenyl-1,2′-biimidazole, 2,2′-bis(2,4-dibromophenyl)-4,4′,5,5′-tetraphenyl-1,2′-biimidazole, 2,2′-bis(2,4,6-trichlorophenyl)-4,4′,5,5′-tetraphenyl-1,2′-biimidazole, 3-(2-methyl-2-dimethylaminopropionyl)carbazole, 3,6-bis(2-methyl-2-morpholinopropionyl)-9-n-dodecylcarbazole, 1-hydroxycyclohexylphenylketone, bis(η⁵-2,4-cyclopentadiene-1-yl)-bis(2,6-difluoro-3-(1H-pyrrole-1-yl)-phenyl)titanium, bis(2,4,6-trimethylbenzoyl)phenylphosphineoxide and 2,4,6-trimethylbenzoyldiphenylphosphineoxide.

Among the above-described examples, bis(2,4,6-trimethylbenzoyl)phenylphosphineoxide, 2,4,6-trimethylbenzoyldiphenylphosphineoxide or the like is a photopolymerization initiator having a phosphorus atom and therefore is preferably used since the adhesiveness of a cured film obtained to copper foil is improved by the use.

1.4. Solvent

The above-described ink-jet ink may comprise a solvent, for example, in order to adjust the viscosity of the ink in accordance with an application of the ink. The solvent has a boiling point of preferably approximately 100 to approximately 300° C., more preferably approximately 150 to approximately 300° C., and even more preferably approximately 200 to approximately 300° C.

Specific examples of such solvents include water, butyl acetate, butyl propionate, ethyl lactate, methyl oxyacetate, ethyl oxyacetate, butyl oxyacetate, methyl methoxyacetate, ethyl methoxyacetate, butyl methoxyacetate, methyl ethoxyacetate, ethyl ethoxyacetate, methyl 3-oxypropionate, ethyl 3-oxypropionate, methyl 3-methoxypropionate, ethyl 3-methoxypropionate, methyl 3-ethoxypropionate, ethyl 3-ethoxypropionate, methyl 2-oxypropionate, ethyl 2-oxypropionate, propyl 2-oxypropionate, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, ethyl 2-ethoxy-2-methylpropionate, methyl pyruvate, ethyl pyruvate, propyl pyruvate, methyl acetoacetate, ethyl acetoacetate, methyl 2-oxobutanate, ethyl 2-oxobutanate, dioxane, ethylene glycol, diethylene glycol, triethylene glycol, propylene glycol, dipropylene glycol, tripropylene glycol, 1,4-butanediol, ethylene glycol monoisopropyl ether, ethylene glycol monobutyl ether, propylene glycol monomethyl ether, propylene glycol monomethyl ether acetate, propylene glycol monoethylether acetate, propylene glycol monopropylether acetate, dipropylene glycol monoethylether acetate, dipropylene glycol monobutylether acetate, ethylene glycol monobutylether acetate, cyclohexanone, cyclopentanone, diethylene glycol monomethyl ether, diethylene glycol monomethyl ether acetate, diethylene glycol monoethyl ether, diethylene glycol monoethyl ether acetate, diethylene glycol monobutyl ether, diethylene glycol monobutyl ether acetate, diethylene glycol dimethyl ether, diethylene glycol diethyl ether, diethylene glycol methyl ethyl ether, toluene, xylene, anisole, gamma-butyrolactone, N,N-dimethylacetamide, N-methyl-2-pyrrolidone and dimethylimidazolidinone.

1.5. Contents of Basic Components in the Ink-Jet Ink

The above-described ink-jet ink may comprise not only at least one compound selected from compounds represented by the general formula (1) and compounds represented by the general formula (2), but also a photopolymerization initiator and a solvent optionally. The contents of these basic components are as described below. Each of the compound represented by the formula (1), the compound represented by the formula (2), the photopolymerization initiator and the solvent may be one type of compound or a mixture of two or more different compounds.

It is preferred that the ink-jet ink comprises compounds represented by the formula (1) and/or compounds represented by the formula (2), since the contact angle on polyimide and copper foil is higher. Based on the whole weight of the ink-jet ink, the total weight of the compounds represented by the formula (1) and the compounds represented by the formula (2) (or the total weight of the compounds represented by the formula (3) and the compounds represented by the formula (4)) is preferably approximately 50 to approximately 100 wt %, more preferably approximately 55 to approximately 95 wt %, and even more preferably approximately 60 to approximately 90 wt %. Further, when the ink comprises both the compounds represented by the formula (1) and the compounds represented by the formula (2), the ratio between them (based on weight) is preferably from approximately 1:10 to approximately 2:1, more preferably from approximately 1:5 to approximately 2:1, and even more preferably from approximately 1:3 to approximately 2:1.

Based on the whole weight of the ink-jet ink, the amount of the photopolymerization initiator to be contained in the ink-jet ink is preferably approximately 0.1 to approximately 20 wt %, more preferably approximately 0.5 to approximately 15 wt %, and even more preferably approximately 1 to approximately 10 wt %. The above-described range is preferably used since a film can be cured with a low irradiance level of ultraviolet.

Based on the whole weight of the ink-jet ink, the amount of the solvent to be contained in the ink-jet ink is preferably approximately 0 to approximately 10 wt %, more preferably approximately 0 to approximately 5 wt % and even more preferably approximately 0 wt %. The above-described range is preferably used since change of the viscosity at the time of jetting is small and therefore stable discharge can be provided.

Moreover, to the above-described ink-jet ink, a different radical polymerizable monomer, a compound having 2 or more oxiranes or oxetanes, an epoxy curing agent, a surfactant, a coupling agent, a coloring agent, a polymerization inhibitor and the like as described below can be added within the range in accordance with the purpose of the invention. These other additives (other than the “different radical polymerizable monomer”) are added in an amount which gives no or almost no influence to the effects exerted by the above-described basic components. Further, such additives are added so that the total content of all the components becomes 100 wt % of the inkjet ink by supplementing the above-described basic components. When the different radical polymerizable monomer is added, it can be supplementarily added as a part of the above-described compounds represented by the formulae (1) and (2).

1.6. Different Radical Polymerizable Monomer

The above-described ink-jet ink may comprise a different radical polymerizable monomer (not the compounds represented by the above-described general formulae (1) to (4)) in order to improve, for example, heat resistance, adhesiveness, flexibility or the like of a cured film obtained. Examples of the “different radical polymerizable monomers” include glycidyl (meth)acrylate, 3,4-epoxy cyclohexyl (meth)acrylate, methylglycidyl (meth)acrylate, 3-methyl-3-(meth)acryloxymethyloxetane, 3-ethyl-3-(meth)acryloxymethyloxetane, 3-methyl-3-(meth)acryloxyethyloxetane, 3-ethyl-3-(meth)acryloxyethyloxetane, p-vinylphenyl-3-ethyloxeta-3-ylmethyl ether, 2-phenyl-3-(meth)acryloxymethyloxetane, 2-trifluoromethyl-3-(meth)acryloxymethyloxetane, 4-trifluoromethyl-2-(meth)acryloxymethyloxetane, (meth)acrylic acid, crotonic acid, α-chloracrylic acid, cinnamic acid, maleic acid, fumaric acid, itaconic acid, citraconic acid, mesaconic acid, ω-carboxypolycaprolactone mono(meth)acrylate, mono[2-(meth)acryloyloxyethyl]succinate, mono[2-(meth)acryloyloxyethyl]maleate, methyl (meth)acrylate, ethyl (meth)acrylate, isopropyl (meth)acrylate, n-butyl (meth)acrylate, isobutyl (meth)acrylate, t-butyl (meth)acrylate, 2-ethylhexyl (meth)acrylate, hexyl (meth)acrylate, cyclohexyl (meth)acrylate, octyl (meth)acrylate, tridecyl (meth)acrylate, lauryl (meth)acrylate, stearyl (meth)acrylate, phenyl (meth)acrylate, benzyl (meth)acrylate, 2-methoxyethyl (meth)acrylate, 2-ethoxyethoxyethyl (meth)acrylate, 3-methoxybutyl (meth)acrylate, phenoxyethyl (meth)acrylate, cetyl (meth)acrylate, isobornyl (meth)acrylate, N,N-dimethylaminoethyl (meth)acrylate, quaternized N,N-dimethylaminoethyl (meth)acrylate, morpholinoethyl (meth)acrylate, trimethylsiloxyethyl (meth)acrylate, cyclohexene-3,4-dicarboxylic acid-(2-mono(meth)acryloyloxy)ethyl, 3-cyclohexenylmethyl (meth)acrylate, 2-tetrahydrophthalimide ethyl (meth)acrylate, (meth)acrylamide, dimethylaminopropyl (meth)acrylamide, N,N-dimethylacrylamide, styrene, α-methyl styrene, maleic anhydride, itaconic acid anhydride, N-vinyl-2-pyrrolidone, 4-acryloyl morpholine, N-phenylmaleimide, N-cyclohexylmaleimide; KAYARAD TC-110S (trade name, manufactured by Nippon Kayaku Co., Ltd.); Biscoat #193, Biscoat #320, Biscoat #2311HP, Biscoat #220, Biscoat #2000, Biscoat #2100, Biscoat #2150, Biscoat #2180, Biscoat 3F, Biscoat 3FM, Biscoat 4F, Biscoat 4FM, Biscoat 6FM, Biscoat 8F, Biscoat 8FM, Biscoat 17F, Biscoat 17FM, Biscoat MTG (trade names, manufactured by Osaka Organic Chemical Industry Ltd.); M-101, M-102, M-110, M-113, M-117, M-120, M-5300, M-5600, M-5700, TO-850, TO-851, TO-1248, TO-1248, TO-1249, TO-1301, TO-1317, TO-1315, TO-981, TO-1215, TO-1316, TO-1322, TO-1342, TO-1340, TO-1225 (trade names, manufactured by Toagosei Co., Ltd.); ethylene oxide isocyanurate-modified di(meth)acrylate, ethylene oxide isocyanurate-modified tri(meth)acrylate, pentaerythritol di(meth)acrylate, pentaerythritol di(meth)acrylate monostearate, pentaerythritol tri(meth)acrylate, pentaerythritol tetra(meth)acrylate, trimethylolpropane di(meth)acrylate, trimethylolpropane tri(meth)acrylate, dipentaerythritol di(meth)acrylate, dipentaerythritol tri(meth)acrylate, dipentaerythritol tetra(meth)acrylate, dipentaerythritol penta(meth)acrylate, dipentaerythritol hexa(meth)acrylate, bisphenol F ethylene oxide-modified di(meth)acrylate, bisphenol A ethylene oxide-modified di(meth)acrylate, polyethyleneglycol di(meth)acrylate, polypropyleneglycol di(meth)acrylate, 1,4-butanediol di(meth)acrylate, 1,6-hexanediol di(meth)acrylate, 1,9-nonanediol di(meth)acrylate, 1,4-cyclohexanedimethanol di(meth)acrylate, 2-n-butyl-2-ethyl-1,3-propanediol di(meth)acrylate, ethylene oxide-modified trimethylolpropane tri(meth)acrylate, propylene oxide-modified trimethylolpropane tri(meth)acrylate, epichlorohydrin-modified trimethylolpropane tri(meth)acrylate, ditrimethylolpropane tetra(meth)acrylate, glycerol tri(meth)acrylate, epichlorohydrin-modified glycerol tri(meth)acrylate, diglycerin tetra(meth)acrylate, and ethylene oxide-modified tri(meth)acrylate phosphate.

Among the above-described examples, from the viewpoint of improving “heat resistance” of a cured film obtained, (meth)acrylic acid, maleic anhydride, itaconic acid anhydride, N-phenylmaleimide, or N-cyclohexylmaleimide is preferable.

From the viewpoint of improving “adhesiveness” of a cured film obtained, ω-carboxypolycaprolactone mono(meth)acrylate, mono[2-(meth)acryloyloxyethyl]succinate or mono[2-(meth)acryloyloxyethyl]maleate is preferable.

From the viewpoint of improving “flexibility” of a cured film obtained, tridecyl (meth)acrylate, lauryl (meth)acrylate, stearyl (meth)acrylate or KAYARAD TC-110S is preferable.

From the viewpoint of improving “photocurability” of an ink-jet ink, diglycerin tetra(meth)acrylate, ditrimethylolpropane tetra(meth)acrylate, ethylene oxide isocyanurate-modified tri(meth)acrylate, pentaerythritol tetra(meth)acrylate or dipentaerythritol hexa(meth)acrylate is preferable. When using these substances, solidification can be performed with a smaller amount of ultraviolet irradiation.

The “different radical polymerizable monomer” may be one type of compound or a mixture of two or more types of compounds. Basically, as described above, the content of the different radical polymerizable monomer is adjusted so that the content of all the components becomes 100 wt % of the ink-jet ink by solely supplementing the above-described basic components or jointly supplementing them with other additives. Based on the whole weight of the ink-jet ink, it is preferably approximately 0 to approximately 50 wt %, more preferably approximately 0 to approximately 30 wt %, and even more preferably approximately 0 to approximately 15 wt %.

1.7. Compounds Having Two or More Oxiranes or Oxetanes

For example, in order to improve chemical resistance of a cured film obtained, the above-described ink-jet ink may comprise a compound having two or more oxiranes or oxetanes. As the compound having two or more oxiranes or oxetanes, en epoxy resin, by which a cured film having good chemical resistance can be obtained, is particularly preferable. Specific examples of epoxy resins include a bisphenol A type epoxy resin, a glycidyl ester type epoxy resin and an alicyclic epoxy resin. Specific examples of these epoxy resins include “Epikote 807”, “Epikote 815”, “Epikote 825”, “Epikote 827”, “Epikote 828”, “Epikote 190P”, “Epikote 191P” (trade names, manufactured by Yuka Shell Epoxy Co., Ltd.); “Epikote 1004”, “Epikote 1007”, “Epikote 1256” (trade names, manufactured by Japan Epoxy Resins Co., Ltd.); “Araldite CY177”, “Araldite CY184” (trade names, manufactured by Nihon Ciba-Geigy K.K.); “Celloxide 2021P”, “EHPE-3150” (trade names, manufactured by Daicel Chemical Industries, Ltd.); and “TECHMORE VG310L” (trade name, manufactured by Mitsui Chemicals, Inc.). Among the above-described examples, Epikote 1004, Araldite CY184, TECHMORE VG3101L and Celloxide 2021P are preferable in terms of their high heat resistance and chemical resistance.

The compound having two or more oxiranes or oxetanes may be one type of compound or a mixture of two or more types of compounds. Basically, as described above, the content of the compound having two or more oxiranes or oxetanes is adjusted so that the content of all the components becomes 100 wt % of the ink-jet ink by solely supplementing the above-described basic components or jointly supplementing them with other additives. Based on the whole weight of the ink-jet ink, it is preferably approximately 0 to approximately 50 wt %, more preferably approximately 0 to approximately 30 wt %, and even more preferably approximately 0 to approximately 15 wt %.

1.8. Epoxy Curing Agent

For example, in order to improve heat resistance of a cured film, the above-described ink-jet ink may comprise an epoxy curing agent. Examples of epoxy curing agents include acid anhydride-based curing agents, polyamine-based curing agents, polyphenol-based curing agents and catalyst-type curing agents. In terms of heat resistance, acid anhydride-based curing agents are preferable.

Specific examples of the acid anhydride-based curing agents include maleic anhydride, tetrahydrophthalic anhydride, hexahydrophthalic anhydride, methylhexahydrophthalic anhydride, hexahydrotrimellitic anhydride, phthalic anhydride, trimellitic anhydride, itaconic anhydride and styrene-maleic anhydride copolymer. Among the above-described examples, trimellitic anhydride, hexahydrotrimellitic anhydride or the like, which is particularly excellent in heat resistance, is preferable.

The epoxy curing agent may be one type of compound or a mixture of two or more types of compounds. Basically, as described above, the content of the epoxy curing agent is adjusted so that the content of all the components becomes 100 wt % of the ink-jet ink by solely supplementing the above-described basic components or jointly supplementing them with other additives. Based on the whole weight of the ink-jet ink, it is preferably approximately 0 to approximately 15 wt %, more preferably approximately 0 to approximately 10 wt %, and even more preferably approximately 0 to approximately 5 wt %.

1.9. Surfactant

For example, in order to improve wettability with respect to a substrate and homogeneity of a cured film surface, the above-described ink-jet ink may comprise a surfactant. Examples of surfactants include silicon-based surfactants, acrylic surfactants and fluorine-based surfactants. Specific examples of the surfactants include: silicon-based surfactants such as Byk-300, Byk-306, Byk-335, Byk-310, Byk-341, Byk-344, and Byk-370 (trade names, manufactured by BYK-Chemie GmbH) and the like; acrylic surfactants such as Byk-354, ByK-358, and Byk-361 (trade names, manufactured by BYK-Chemie GmbH) and the like; DFX-18, FTERGENT 250, FTERGENT 251 (trade names, manufactured by Neos Company Limited) and the like.

The surfactant may be one type of compound or a mixture of two or more types of compounds. Basically, as described above, the content of the surfactant is adjusted so that the content of all the components becomes 100 wt % of the ink-jet ink by solely supplementing the above-described basic components or jointly supplementing them with other additives. Based on the whole weight of the ink-jet ink, it is preferably approximately 0 to approximately 1 wt %, more preferably approximately 0 to approximately 0.5 wt %, and even more preferably approximately 0 to approximately 0.2 wt %.

1.10. Coupling Agent

For example, in order to improve adhesiveness to a substrate, the above-described ink-jet ink may comprise a coupling agent. For example, silane-based, aluminum-based and titanate-based compounds can be used as the coupling agents. Specific examples of the coupling agents include: silane-based compounds such as 3-glycidoxypropyl dimethylethoxysilane, 3-glycidoxypropyl methyldiethoxysilane, 3-glycidoxypropyl trimethoxysilane and the like; aluminum-based compounds such as acetalkoxy aluminum diisopropylate and the like; and titanate-based compounds such as tetraisopropyl bis(dioctylphosphite)titanate and the like. Among them, 3-glycidoxypropyl trimethoxysilane is preferable since it improves adhesiveness more effectively.

The coupling agent may be one type of compound or a mixture of two or more types of compounds. Basically, as described above, the content of the coupling agent is adjusted so that the content of all the components becomes 100 wt % of the ink-jet ink by solely supplementing the above-described basic components or jointly supplementing them with other additives. Based on the whole weight of the ink-jet ink, it is preferably approximately 0 to approximately 10 wt %, more preferably approximately 0 to approximately 5 wt %, and even more preferably approximately 0 to approximately 2 wt %.

1.11. Coloring Agent

For example, in order to facilitate distinguishment from a substrate to examine the state of a cured film, the above-described ink-jet ink may comprise a coloring agent. As the coloring agent, a pigment is preferable since it has good heat resistance. The coloring agent may be one type of compound or a mixture of two or more types of compounds. Basically, as described above, the content of the coloring agent is adjusted so that the content of all the components becomes 100 wt % of the ink-jet ink by solely supplementing the above-described basic components or jointly supplementing them with other additives. Based on the whole weight of the ink-jet ink, it is preferably approximately 0 to approximately 10 wt %, more preferably approximately 0 to approximately 7 wt %, and even more preferably approximately 0 to approximately 5 wt %.

1.12. Polymerization Inhibitor

For example, in order to improve preservation stability (change in viscosity of ink, etc.), the above-described ink-jet ink may comprise a polymerization inhibitor. Specific examples of polymerization inhibitors include 4-methoxyphenol, hydroquinone and phenothiazine. Among them, phenothiazine is preferable since change of its viscosity is small during long-term storage. The polymerization inhibitor may be one type of compound or a mixture of two or more types of compounds. Basically, as described above, the content of the polymerization inhibitor is adjusted so that the content of all the components becomes 100 wt % of the ink-jet ink by solely supplementing the above-described basic components or jointly supplementing them with other additives. Based on the whole weight of the ink-jet ink, it is preferably approximately 0 to approximately 1 wt %, more preferably approximately 0 to approximately 0.5 wt %, and even more preferably approximately 0 to approximately 0.2 wt %.

2. Method for Forming a Cured Film

As the method for forming a cured film, for example, by discharging the above-described ink-jet ink from an ink-jet head onto a substrate at a discharging temperature of approximately 80 to approximately 150° C. and heating it, a highly-fine patterned cured film can be formed. The discharging temperature of approximately 90 to approximately 140° C. is more preferable since a highly-fine pattern can be compatible with the stability of discharge. Even more preferably, the discharging temperature is approximately 100 to approximately 130° C. Heating after discharge can be performed using, for example, an oven, a hot plate or the like. Further, the heating temperature and heating time can be determined depending on the type of a heating device, components contained in the ink-jet ink, physical properties of a desired cured film and the like. For example, heating is preferably performed at approximately 160 to approximately 300° C. for approximately 5 to approximately 90 minutes, more preferably at approximately 180 to approximately 280° C. for approximately 10 to approximately 60 minutes, and even more preferably at approximately 200 to approximately 260° C. for approximately 15 to approximately 40 minutes.

When both the above-described photopolymerization initiator and the compound represented by the formula (2) are contained or both the photopolymerization initiator and the above-described different radical polymerizable monomer are contained, a cured film can be formed by discharging the ink-jet ink on a substrate and thereafter irradiating the ink with ultraviolet light, visible light or the like. An irradiated portion of the discharged ink is cured by means of polymerization of the compound of formula (1) in which R¹ has a polymerizable double bond, the compound of formula (2) or the different radical polymerizable monomer. Since the spread of the ink can be effectively inhibited thereby, it is possible to draw a highly-fine pattern. When ultraviolet light is used as a light for irradiation, the amount of ultraviolet light can be determined based on components contained in the ink-jet ink, physical properties of a desired cured film and the like. When measurement is performed using an integrating photometer (accumulated UV Meter) UIT-201 equipped with a photoreceiver UVD-365PD manufactured by Ushio Inc., the amount is preferably approximately 1 to approximately 1,000 mJ/cm², more preferably approximately 5 to approximately 500 mJ/cm², and even more preferably approximately 10 to approximately 300 mJ/cm² . Additionally, heating and burning are preferably performed using an oven or a hot plate since heat resistance and chemical resistance are improved thereby. Regarding heating temperature and heating time at this time, for example, heating is preferably performed at approximately 160 to approximately 300° C. for approximately 5 to approximately 90 minutes, more preferably at approximately 180 to approximately 280° C. for approximately 10 to approximately 60 minutes, and even more preferably at approximately 200 to approximately 260° C. for approximately 15 to approximately 40 minutes.

The term “substrate” as used herein is not particularly limited as long as it can be an object to be coated with the ink-jet ink. The form of the substrate may be a flat surface type or a curved surface type. Further, though the thickness of the substrate is not particularly limited, it is generally approximately 10 μm to approximately 2 mm and is suitably adjusted according to purpose of use thereof. It is preferably approximately 15 to approximately 500 μm, and more preferably approximately 20 to approximately 200 μm. Moreover, according to need, to the surface of the substrate on which a cured film is formed, a treatment to facilitate adhesion such as a corona treatment, a plasma treatment and a blast treatment can be applied, and a layer to facilitate adhesion can be provided.

A material of the substrate is not particularly limited. Examples thereof include: polyester-based resins such as polyethylene terephthalate (PET) and polybutylene terephthalate (PBT); polyolefin resins such as polyethylene and polypropylene; plastic films such as polyvinyl chloride, fluorine resin, acrylic resin, polyamide, polycarbonate and polyimide; laminated films of cellophane, acetate, metallic foil, polyimide and metallic foil and the like; paper, glass and the like which has been subjected to a sealing treatment using glassine paper or parchment paper having the sealing effect, or polyethylene, a clay binder, polyvinyl alcohol, starch, carboxymethylcellulose (CMC) or the like. Such materials constituting the substrate may further comprise additives such as a pigment, a dye, an antioxidant, an antidegradant, a filler, an ultraviolet absorber, an antistatic agent and/or an electromagnetic inhibitor and the like within a range in which the effect of the invention is not adversely affected thereby.

It will be apparent to those skilled in the art that various modifications and variations can be made in the invention and specific examples provided herein without departing from the spirit or scope of the invention. Thus, it is intended that the invention covers the modifications and variations of this invention that come within the scope of any claims and their equivalents.

The following examples are for illustrative purposes only and are not intended, nor should they be interpreted to, limit the scope of the invention.

### EXAMPLES

Hereinafter, the invention will be further described in detail by way of examples, but the invention is not limited thereto.

### Example 1

Ripoxy HFA-6127 (trade name; manufactured by Showa Highpolymer Co., Ltd.; a product obtained by an addition reaction between caprolactone-modified dipentaerythritol hexaacrylate and HCA; as the compound represented by the general formula (1)), 4-hydroxybutyl acrylate (hereinafter referred to as “4HBA”; as the compound represented by the general formula (2)), DAROCUR TPO (trade name; manufactured by Ciba Specialty Chemicals; 2,4,6-trimethylbenzoyl-diphenylphosphineoxide; hereinafter referred to as “TPO”; as the photopolymerization initiator), and phenothiazine (as the polymerization inhibitor) were mixed and dissolved together in the following composition. The mixture was filtered using a membrane filter made of fluorine resin having the pore diameter of 1 μm to prepare an ink-jet ink 1. The viscosity of the ink at 25° C. was 171 mPa·s.

| | |
|---|---|
| HFA-6127 | 12.00 g |
| 4HBA | 10.00 g |
| TPO | 0.50 g |
| Phenothiazine | 0.01 g |

Next, the ink-jet ink 1 was put into an ink-jet cartridge, the cartridge was applied to an ink-jet apparatus DMP-2811 (trade name, manufactured by Dimatix, Inc.), and drawing was performed on a polyimide film, Kapton® (trade name, manufactured by Du Pont-Toray Co., Ltd., thickness of 150 μm, H type; hereinafter referred to as “Kapton substrate”). Under the drawing conditions at that time, the width of lines was changed in a stepwise fashion (every 10 μm) from 20 μm to 200 μm, and corresponding thereto, the width of spaces between lines was also changed in a stepwise fashion (every 10 μm) from 20 μm to 200 μm (hereinafter referred to as “line & space pattern”). Application was performed once. The length of lines was 50 mm. The rate of jetting from a nozzle was 10 drops/sec. The jetting temperature was 105° C.

The substrate after drawing was irradiated with ultraviolet light having the wavelength of 365 nm (30 mJ/cm²), and after that, it was burned at 200° C. for 30 minutes to obtain the Kapton substrate on which the line & space pattern was formed. When the substrate was observed using a microscope, in the case of the pattern in which the width of lines (spaces) was 20 μm, the width of lines was broadened and the spaces were blurred. However, the line & space pattern in which the width of lines (spaces) is 30 μm more was successfully drawn. That is, fine patterns were successfully produced.

### Comparative Example 1

An ink-jet ink 2 was prepared in the following composition in a manner similar to that in Example 1. The viscosity of the ink at 25° C. was 16 mPa·s.

| | |
|---|---|
| HFA-6127 | 2.00 g |
| 4HBA | 10.00 g |
| TPO | 0.27 g |
| Phenothiazine | 0.01 g |

When the ink-jet 2 was evaluated in a manner similar to that in Example 1 except that the jetting temperature was 25° C., drawing was successfully performed only in the case of the line & space pattern in which the width of lines (spaces) was 180 μm or more. That is, fine patterns could not be produced.

### Comparative Example 2

An ink-jet ink 3 was prepared in the following composition in a manner similar to that in Example 1. The viscosity of the ink at 25° C. was 522 mPa·s.

| | |
|---|---|
| HFA-6127 | 16.00 g |
| 4HBA | 8.00 g |
| TPO | 0.65 g |
| Phenothiazine | 0.01 g |

When the ink-jet ink 3 was heated in an oven at 170° C. for 1 hour, the ink was solidified. When an ink-jet ink is discharged at a high temperature, if only a nozzle portion is heated, the ink does not reach a predetermined temperature. Therefore, a portion to supply the ink to the nozzle or the entire ink cartridge must be heated. As a result, the ink is exposed to a high temperature for a long period of time. In the case of such an ink-jet ink that is discharged at a high temperature, it is at least required that the viscosity of the ink is not changed even if it is heated at a discharging temperature for 1 hour. Therefore, it was judged that it is impossible to discharge the ink at 170° C.

### Comparative Example 3

An ink-jet ink 4 was prepared in the following composition in a manner similar to that in Example 1. The viscosity of the ink at 25° C. was 166 mPa·s.

| | |
|---|---|
| Bisphenol A diethylene glycol diacrylate | 10.00 g |
| (ARONIX (trade name) M210 manufactured by | |
| Toagosei Co., Ltd.) | |
| Pentaerythritol Hexaacrylate | 10.00 g |
| Dipropylene glycol monoethylether acetate | 4.00 g |
| TPO | 0.65 g |
| Phenothiazine | 0.01 g |

When the ink-jet ink 4 was evaluated in a manner similar to that in Example 1 except that the jetting temperature was 100° C., drawing was successfully performed only in the case of the line & space pattern in which the width of lines (spaces) was 80 μm or more. That is, fine patterns could not be produced.

### INDUSTRIAL APPLICABILITY

According to the method for forming a cured film of the invention, highly-fine patterns can be formed by means of the ink-jet method, and it is useful as a method for forming a cured film for an electronic circuit substrate.

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

What is claimed is:

1. A method for forming a cured film comprising:
discharging an ink-jet ink,
wherein the ink-jet ink comprises at least one compound selected from the group consisting of compounds represented by general formula (1) and compounds represented by general formula (2), and
wherein the ink-jet ink has a viscosity at 25° C. of approximately 150 mPa·s to approximately 3,000 mPa·s,
from an ink-jet head at a discharging temperature of approximately 80° C. to approximately 150° C., 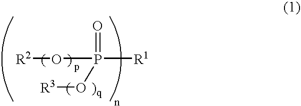
wherein in the formula (1), R¹ is an organic group having 1 to 100 carbon atoms; R² and R³ are each independently alkyl having 1 to 20 carbon atoms, phenyl, phenyl in which any hydrogen is replaced by alkyl having 1 to 5 carbon atoms, or phenyl in which any hydrogen is replaced by phenyl, wherein R² and R³ may bind to each other to form a cyclic group(s); n is an integer from 1 to 10; and p and q are each independently 0 or 1, and 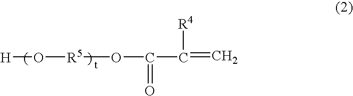
wherein in the formula (2), R⁴ is hydrogen or methyl; R⁵ is alkylene having 2 to 20 carbon atoms which may have a cyclic structure(s); and t is an integer from 1 to 30.

2. The method for forming a cured film of claim 1,
wherein the ink-jet ink comprises at least one compound selected from compounds represented by the general formula (1) and at least one compound selected from compounds represented by the general formula (2).

3. A method for forming a cured film comprising:
discharging an ink-jet ink,
wherein the ink-jet ink comprises at least one compound selected from the group consisting of compounds represented by general formula (3) and compounds represented by general formula (4), and
wherein the ink-jet ink has a viscosity at 25° C. of approximately 150 mPa·s to approximately 3,000 mPa·s,
from an ink-jet head at a discharging temperature of approximately 80° C. to approximately 150° C., 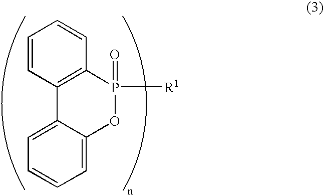
wherein in the formula (3), R¹ is an organic group having 1 to 100 carbon atoms; and n is an integer from 1 to 10, and 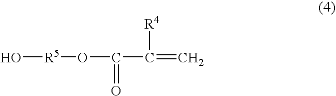
wherein in the formula (4), R⁴ is hydrogen or methyl; and R⁵ is alkylene having 2 to 8 carbon atoms which may have a cyclic structure(s).

4. The method for forming a cured film of claim 3,
wherein the ink-jet ink comprises at least one compound selected from compounds represented by the general formula (3) and at least one compound selected from compounds represented by the general formula (4).

5. The method for forming a cured film of claim 1, wherein the ink-jet ink further comprises a photopolymerization initiator.

6. The method for forming a cured film of claim 5, wherein the ink-jet ink comprises a solvent, wherein the solvent has a boiling point under ordinary pressure of approximately 300° C. or lower, and wherein the solvent is approximately 0 wt % to approximately 10 wt % based on total weight of the ink-jet ink.

7. The method for forming a cured film of claim 5, wherein the photopolymerization initiator is selected from the group consisting of bis(2,4,6-trimethylbenzoyl)phenylphosphineoxide and 2,4,6-trimethylbenzoyldiphenylphosphineoxide.

8. (canceled)

9. The method for forming a cured film of claim 1, wherein R¹ is an organic group having 1 to 100 carbon atoms which has a radical polymerizable double bond.

10. The method for forming a cured film of claim 1, wherein R⁵ is ethylene, propylene or butylene.

11. The method for forming a cured film of claim 3, wherein the compounds represented by the general formula (3) are selected from the group consisting of compounds represented by general formula (5), (6), (7) and (8), 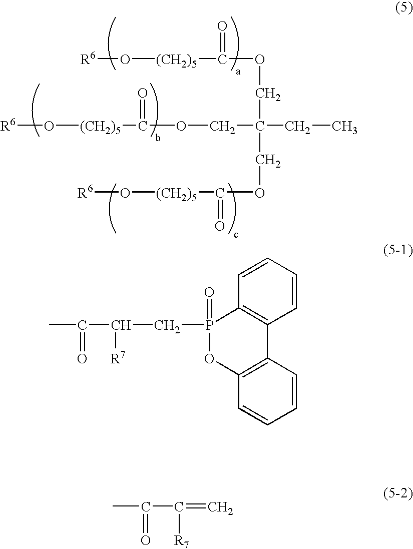
wherein in the formula (5), a, b and c are each independently an integer from 0 to 10; 1 or 2 of three R⁶s are a group represented by the formula (5-1), and the remaining R⁶(s) is a group represented by the formula (5-2); and R⁷ is hydrogen or methyl, 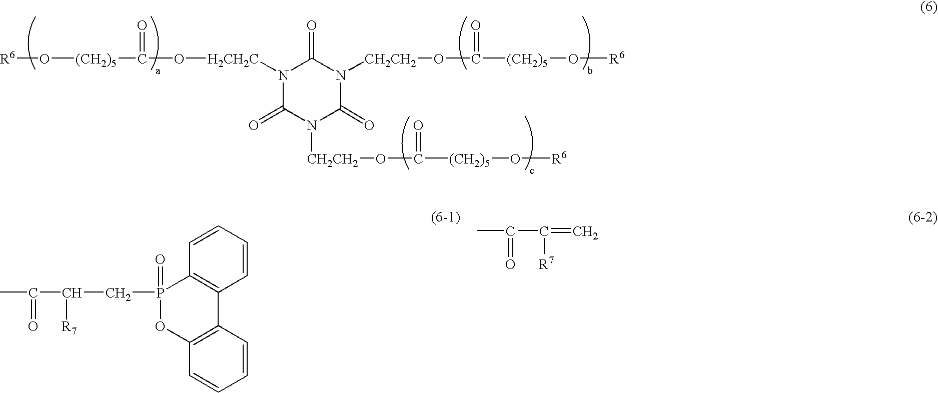
wherein in the formula (6), a, b and c are each independently an integer from 0 to 10; 1 or 2 of three R⁶s are a group represented by the formula (6-1), and the remaining R⁶(s) is a group represented by the formula (6-2); and R⁷ is hydrogen or methyl, 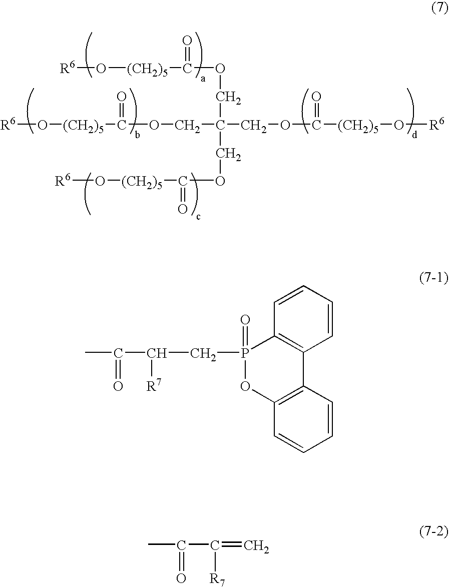
wherein in the formula (7), a, b, c and d are each independently an integer from 0 to 10; 1 to 3 of four R⁶s are a group represented by the formula (7-1), and the remaining R⁶(s) is a group represented by the formula (7-2); and R⁷ is hydrogen or methyl, and 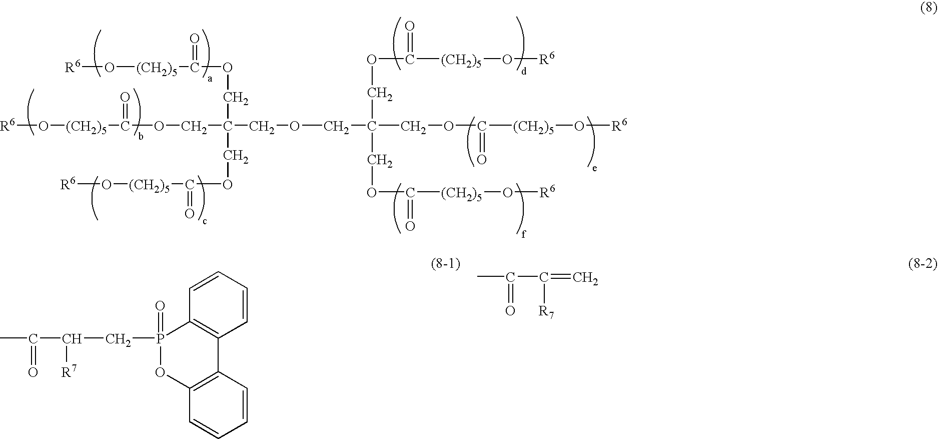
wherein in the formula (8), a, b, c, d, e and f are each independently an integer from 0 to 10; 1 to 5 of six R⁶s are a group represented by the formula (8-1), and the remaining R⁶(s) is a group represented by the formula (8-2); and R⁷ is hydrogen or methyl.

12. The method for forming a cured film of claim 1, wherein the viscosity of the ink-jet ink at 25° C. is approximately 150 to approximately 300 mPa·s.

13. The method for forming a cured film of claim 1, wherein the discharging temperature is approximately 90 to approximately 140° C.

14. (canceled)

15. A cured film formed using the method for forming a cured film of claim 1.

16. A patterned cured film formed using the method for forming a cured film of claim 1.

17. An electronic circuit substrate in which the cured film of 15 is formed on a substrate.

18. An electronic component having the electronic circuit substrate of claim 17.

19. The method for forming a cured film of claim 3, wherein the ink-jet ink further comprises a photopolymerization initiator.

20. The method for forming a cured film of claim 19, wherein the ink-jet ink comprises a solvent, wherein the solvent has a boiling point under ordinary pressure of approximately 300° C. or lower, and wherein the solvent is approximately 0 wt % to approximately 10 wt % based on total weight of the ink-jet ink.

21. The method for forming a cured film of claim 3, wherein R¹ is an organic group having 1 to 100 carbon atoms which has a radical polymerizable double bond.

22. The method for forming a cured film of claim 3, wherein R⁵ is ethylene, propylene or butylene.

23. The method for forming a cured film of claim 3, wherein the viscosity of the ink-jet ink at 25° C. is approximately 150 to approximately 300 mPa·s.

24. The method for forming a cured film of claim 3, wherein the discharging temperature is approximately 90 to approximately 140° C.

25. A cured film formed using the method for forming a cured film of claim 3.

26. A patterned cured film formed using the method for forming a cured film of claim 3.

27. An electronic circuit substrate in which the cured film according to claim 25 is formed on a substrate.

28. An electronic component having the electronic circuit substrate according to claim 27.

29. The method for forming a cured film of claim 6,
wherein the ink-jet ink comprises ingredients where;
the total weight of the compounds is approximately 50 wt % to approximately 100 wt %, wherein the compounds are selected from the group consisting of compounds represented by the general formula (1) and represented by the general formula (2), and compounds represented by the general formula (3) and represented by the general formula (4);
the weight of the solvent is approximately 0 wt % to approximately 10 wt %;
the weight of the photopolymerization initiator is approximately 0 wt % to approximately 20 wt %; and
the total weight of a different radical polymerizable monomer and a compound selected from the group consisting of compounds having two or more oxiranes or oxetanes is approximately 0 wt % to approximately 50 wt %,
based on the whole weight of the ink-jet ink.
